(19) United States
(12) Patent Application Publication
(10) Pub. No.: US 2025/0194155 A1
(43) Pub. Date: Jun. 12, 2025

(54) NANOSHEET FET WITH EXPANDED GATE REGION

(71) Applicant: INTERNATIONAL BUSINESS MACHINES CORPORATION, ARMONK, NY (US)

(72) Inventors: Ruilong Xie, Niskayuna, NY (US); Chen Zhang, Santa Clara, CA (US); Takashi Ando, Eastchester, NY (US); Jingyun Zhang, Albany, NY (US)

(21) Appl. No.: 18/534,093

(22) Filed: Dec. 8, 2023

(51) Int. Cl. H01L 29/423; H01L 23/528; H01L 29/06; H01L 29/417; H01L 29/66; H01L 29/775

(52) U.S. Cl. CPC H10D 30/6735; H01L 23/5286; H10D 30/014; H10D 30/43; H10D 30/6729; H10D 62/121; H10D 64/017

(57) ABSTRACT

A nanosheet field effect transistor (FET) comprises a diffusion region and a gate. The diffusion region connects to a backside power delivery network. The diffusion region is beneath the gate. The gate is in a first gate region. The gate comprises a first gate extension region that extends over the diffusion region.

### BACKGROUND

The present invention relates to nanosheet field effect transistors, and more specifically, to gate shape and contact placement in nanosheet field effect transistors.

Nanosheet field effect transistors are a type of field effect transistor (FET) in which a set of parallel semiconductor sheets (referred to herein as “nanosheets”) are patterned such that they are layered over each other. The set of nanosheets is typically surrounded on each side by gate material (sometimes referred to as “work function metal”) that can be used to switch the state of the FET. Each nanosheet in the set is typically also separated from each other nanosheet by gate material. As a result, each nanosheet in a typical nanosheet FET has high contact area to the FET gate, causing the performance of the FET to be higher than previous FET designs (e.g., planar FETs).

A nanosheet FET is activated by applying current to the work function metal that surrounds the nanosheets. Thus, a typical nanosheet FET requires a gate contact to be routed to the FET gate. These gate contacts are sometimes routed near other contacts for the FET, such as contacts for source/drain epitaxial regions.

### SUMMARY

Some embodiments of the present disclosure can be illustrated as a semiconductor device comprising a nanosheet field effect transistor (FET). The nanosheet FET comprises a diffusion region that connects to a backside power delivery network. The nanosheet FET also comprises a gate in a first gate region. The gate comprises a first gate extension region that extends over the diffusion region.

Some embodiments of the present disclosure can also be illustrated by a nanosheet FET. The nanosheet FET comprises a diffusion region that connects to a backside power delivery network. The nanosheet FET also comprise a gate in a first gate region. The gate comprises a first gate extension region that extends over the diffusion region.

### BRIEF DESCRIPTION OF THE DRAWINGS

FIGS. 1A and 1B illustrate two cross sectional views of a first intermediate stage of forming a first nanosheet FET and second nanosheet FET with gate extensions, in accordance with embodiments of the present disclosure.

FIGS. 2A and 2B illustrate two cross sectional views of a second intermediate stage of forming the first nanosheet FET and second nanosheet FET with gate extensions, in accordance with embodiments of the present disclosure.

FIGS. 3A and 3B illustrate two cross sectional views of a third intermediate stage of forming the first nanosheet FET and second nanosheet FET with gate extensions, in accordance with embodiments of the present disclosure.

FIGS. 4A and 4B illustrate two cross sectional views of a fourth intermediate stage of forming the first nanosheet FET and second nanosheet FET with gate extensions, in accordance with embodiments of the present disclosure.

FIGS. 5A and 5B illustrate two cross sectional views of a fifth intermediate stage of forming the first nanosheet FET and second nanosheet FET with gate extensions, in accordance with embodiments of the present disclosure.

FIGS. 6A and 6B illustrate two cross sectional views of a sixth intermediate stage of forming the first nanosheet FET and second nanosheet FET with gate extensions, in accordance with embodiments of the present disclosure.

FIGS. 7A and 7B illustrate two cross sectional views of a seventh intermediate stage of forming the first nanosheet FET and second nanosheet FET with gate extensions, in accordance with embodiments of the present disclosure.

FIGS. 8A and 8B illustrate two cross sectional views of an eighth intermediate stage of forming the first nanosheet FET and second nanosheet FET with gate extensions, in accordance with embodiments of the present disclosure.

FIGS. 9A and 9B illustrate two cross sectional views of a ninth intermediate stage of forming the first nanosheet FET and second nanosheet FET with gate extensions, in accordance with embodiments of the present disclosure.

FIG. 10 illustrates a cross sectional view of a tenth stage of forming the first nanosheet FET with a gate extensions, in accordance with embodiments of the present disclosure.

FIG. 11 illustrates a cross sectional view of a first intermediate stage of forming a first nanosheet FET with a second embodiment of a gate extension, in accordance with embodiments of the present disclosure.

FIG. 12 illustrates a cross sectional view of a second intermediate stage of forming the nanosheet FET with the second embodiment of a gate extension, in accordance with embodiments of the present disclosure.

FIG. 13 illustrates a cross sectional view of a third intermediate stage of forming the nanosheet FET with the second embodiment of a gate extension, in accordance with embodiments of the present disclosure.

FIG. 14 illustrates a cross sectional view of a fourth intermediate stage of forming the nanosheet FET with the second embodiment of a gate extension, in accordance with embodiments of the present disclosure.

FIG. 15 illustrates a cross sectional view of a fifth stage of forming the first nanosheet FET with the second embodiment of gate extension, in accordance with embodiments of the present disclosure.

### DETAILED DESCRIPTION

The present invention relates to nanosheet field effect transistors, and more specifically, to contact placement in nanosheet field effect transistors.

The flowcharts and cross-sectional diagrams in the Figures illustrate methods of manufacturing stacked FET devices according to various embodiments. In some alternative implementations, the manufacturing steps may occur in a different order that that which is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

A field-effect transistor (FET) may be used for amplifying or switching electronic signals. The wafer footprint of a FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a so-called gate-all-around (GAA) nanosheet FET is a known architecture for providing a relatively small FET footprint by forming the channel region as a series of nanosheets. In a known GAA configuration, a nanosheet-based FET includes a source region, a drain region and stacked nanosheet channels between the source and drain regions.

Semiconductor nanosheet FET devices typically include one or more suspended nanosheets that serve as the channel. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized. For n-type FETs, the channel nanosheets are typically silicon (Si) and the sacrificial nanosheets are typically silicon germanium (SiGe). For p-type FETs, the channel nanosheets can be SiGe and the sacrificial nanosheets can be Si. In some implementations, the channel nanosheet of a p-type FET can be SiGe or Si, and the sacrificial nanosheets can be Si or SiGe. Forming the GAA nanosheets from alternating layers of channel nanosheets formed from a first type of semiconductor material (e.g., Si for n-type FETs, and SiGe for p-type FETs) and sacrificial nanosheets formed from a second type of semiconductor material (e.g., SiGe for n-type FETs, and Si for p-type FETs) provides superior channel electrostatics control, which is necessary for continuously scaling gate lengths down to seven (7) nanometer CMOS technology and below.

Switching a typical GAA nanosheet FET requires activating the gate that surrounds the nanosheets by applying a voltage to the gate material. To enable this application of voltage, a gate contact is landed on the top of the gate material during manufacturing. This gate contact is routed to a metal layer (typically referred to as the first metal layer, or “M1”) in which the gate contact connects to a metal terminal. In typical semiconductor designs, the M1 layer also contains terminals that connect to other contacts for the FET or for other devices. For example, the M1 layer may contain terminals that connect to contacts for the source region, drain region, or both source and drain regions for the FET or for other FETs. These contacts may be referred to herein as source contacts, drain contacts, or source/drain contacts.

Due to the small footprint of typical GAA nanosheet FET designs, the gate contact for a FET may be routed very close to one or more source/drain contacts. This may also cause the metal terminals to which these contacts connect to be very close to each other in the M1 layer. This is not ideal, as slight inconsistencies in manufacturing can result in shorts between these close terminals, leading to malfunctions in design operation.

Some embodiments of the present disclosure enable address this problem by forming a gate extension over a source-drain region adjacent to the gate, which enables the gate contact to be placed over the source/drain region rather than the gate region. This may also result in extra space between the gate contact and any nearby source/drain contacts (i.e., source/drain contacts that do not route to the BSPDN layer), which in turn results in extra space between the corresponding terminals in the M1 layer.

In some embodiments of the present disclosure, this gate extension is made possible by routing at least one source/drain contact to a backside power delivery network layer (also referred to as a BSPDN layer) rather than directly to the M1 layer. The BSPDN layer is typically located on the opposite side of the FET of the M1 layer. Thus, a source/drain region with a source/drain contact that routes to the BSPDN layer does require any real estate between the source-drain region and the M1 layer. For this reason, a gate adjacent to that source/drain region can be extended over the source/drain region, and the gate contact can be landed on that gate extension.

In some embodiments of the present disclosure, landing the gate contact on the gate extension, rather than in the traditional gate region, can reduce the need to maintain all gate material in the traditional gate region. In these embodiments, an enlarged source-drain contact spacer can be formed to reduce capacitance between the gate material and the source-drain contact.

For example, particularly in embodiments in which the gate extension extends well above an adjacent source-drain region, the gate contact may be located significantly away from the traditional gate region. As a result, some of the FET real estate that may otherwise be required for a gate contact landing may be used for other purposes. Some embodiments of the present disclosure, for example, utilize that real estate by forming large insulation layers around a nearby source-drain contact that routes to the M1 layer.

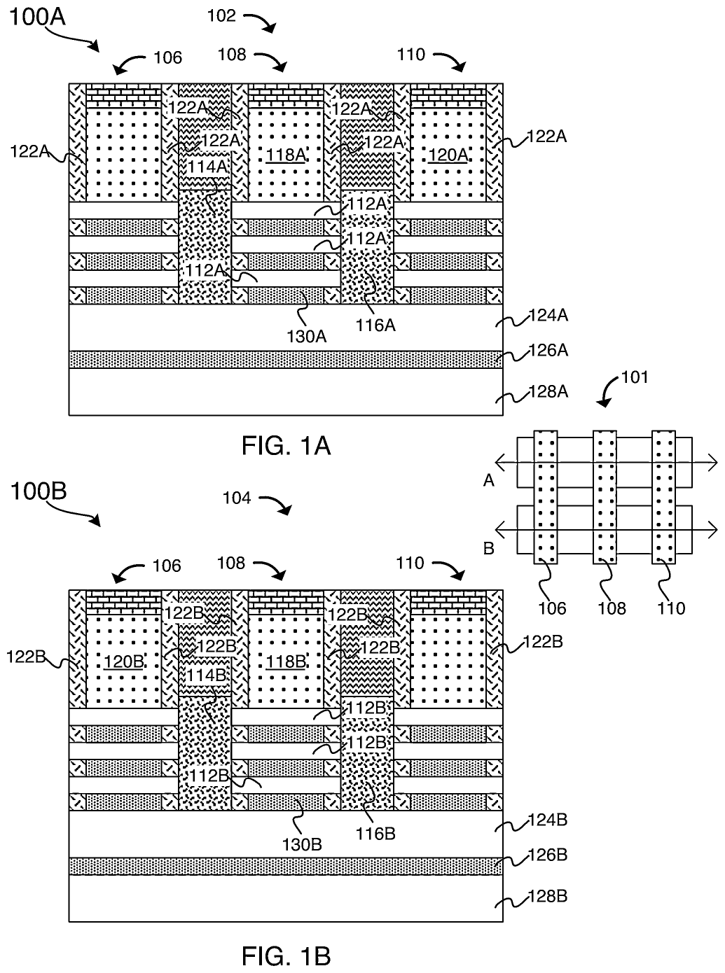

FIGS. 1A and 1B illustrate two cross sectional views 100A and 100B of a first intermediate stage of forming a first nanosheet FET 102 and second nanosheet FET 104 with gate extensions, in accordance with embodiments of the present disclosure. Legend 101 provides a perspective of where FETs 102 and 104 occur in a larger semiconductor structure. Specifically, line A in legend 101 represents the cross section presented in cross sectional view 100A, and line B in legend 101 represents the cross section presented in cross sectional view 100B. For added clarity, gate regions 106, 108, and 110 are visible both in legend 101 and in cross sectional views 100A and 100B.

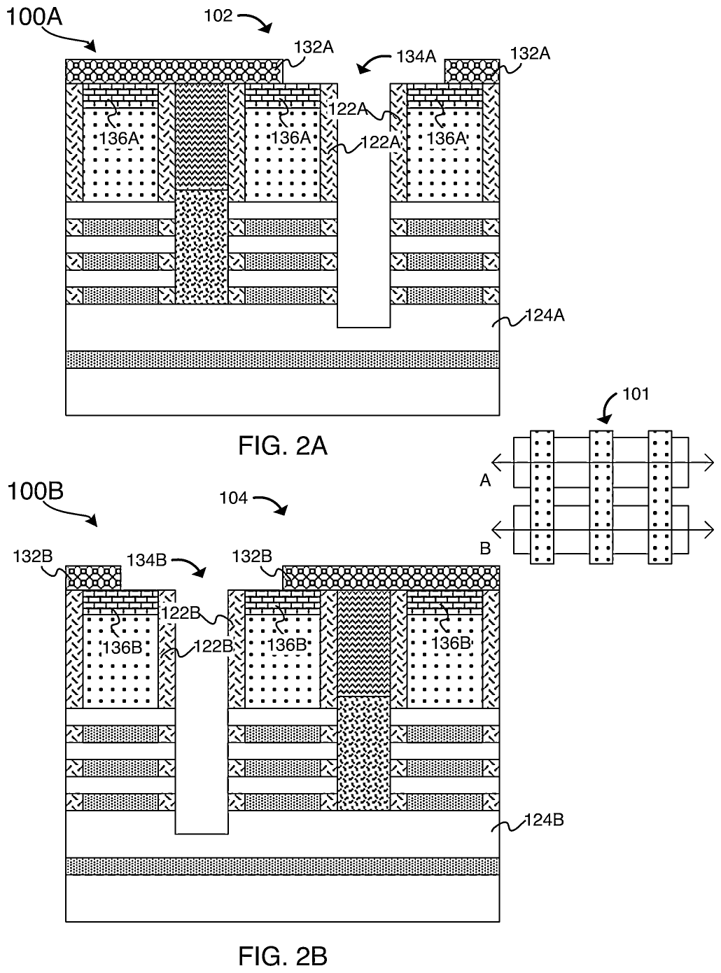

Of note, legend 101 is reproduced in FIGS. 2A-14, and the cross sections represented by lines A and B therein continue to represent the corresponding cross-sectional views in those figures.

As noted, FIGS. 1A and 1B present FETs 102 and 104 in a first intermediate stage of formation. In this stage, FETs 102 and 104 includes nanosheet channels 112A and 112B, diffusion regions 114A, 114B, 116A, and 116B, dummy gate material 118A, and 118B, and gate spacers 122A and 122B. FETs 102 and 104 are formed upon silicon epitaxial layers 124A and 124B, which is separated by silicon substrates 128A and 128B by etch-stop layers 126A and 126B (e.g., a SiGe etch stop layer). Nanosheet channels 112A and 112B are, in the first intermediate stage, partially surrounded by SiGe regions 130A and 130B.

Of note, the overall semiconductor device structure also includes dummy gate material 120A in gate region 110 and dummy gate material 120B in gate region 106. Further of note, in some embodiments some components illustrated as separate components in FIGS. 1A and 1B may actually be a single contiguous material in practice. For example, in some embodiments silicon substrates 128A and 128B may be a single contiguous silicon substrate.

Diffusion regions 114A, 114B, 116A, and 116B may be source regions or drain regions and may be composed of doped silicon. Gate spacers 122A and 122B may be composed of a dielectric material such as silicon nitride (SiN). Etch stop layers 126A and 126B and SiGe regions 130A and 130B may be composed of, for example, SiGe30.

FIGS. 2A and 2B illustrate two cross sectional views 100A and 100B of a second intermediate stage of forming the first nanosheet FET 102 and second nanosheet FET 104 with gate extensions, in accordance with embodiments of the present disclosure. In this second stage, organic planarization layers (OPLs) 132A and 132B have been applied to FETs 102 and 104. This has enabled the formation of patterns for the backside source/drain contacts, shown in FIGS. 2A and 2B as trenches 134A and 134B. Trenches 134A and 134B may have been formed with a timed directional etch, such as reactive ion etching. The etchant used may be highly selective to spacers 122A and 122B and to hardmasks 136A and 136B, causing them to act as etch stops. As illustrated, trenches 134A and 134B extend into silicon epitaxial layers 124A and 124B.

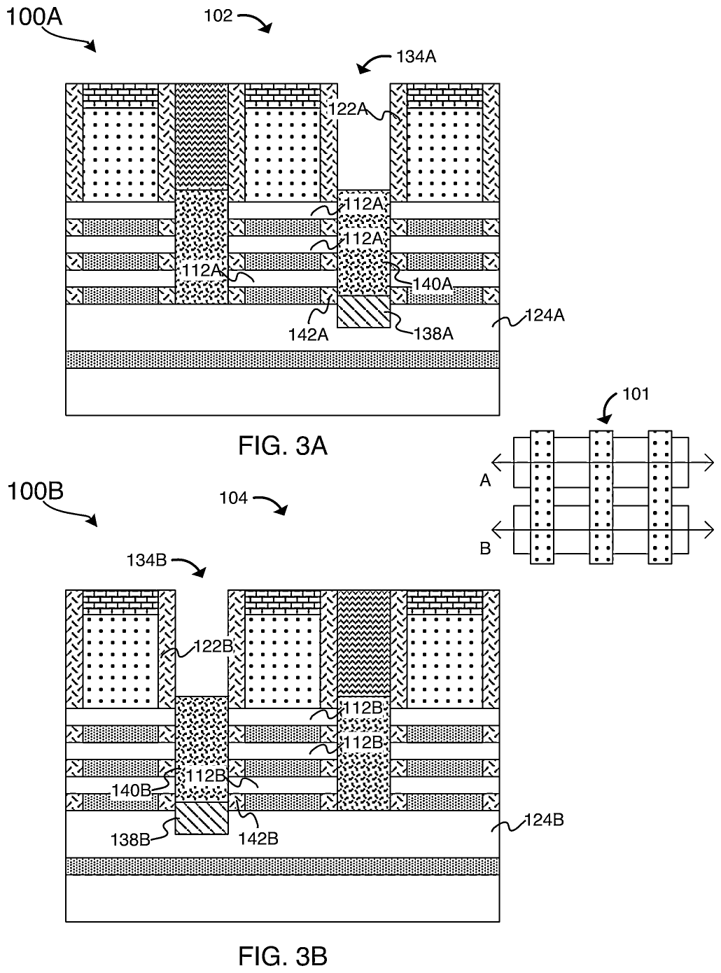

FIGS. 3A and 3B illustrate two cross sectional views 100A and 100B of a third intermediate stage of forming the first nanosheet FET 102 and second nanosheet FET 102 with gate extensions, in accordance with embodiments of the present disclosure. In this third stage, placeholders 138A and 138B have been formed within trenches 134A and 134B. Placeholders 138A and 138B are placeholders for eventual S/D contacts for diffusion regions 140A and 140B. For this reason, placeholders 138A and 138B have been formed in the bottom of trenches 134A and 134B and may, as illustrated, extend into the portion of trenches 134A and 134B that is adjacent to inner spacers 142A and 142B, but do not extend into the portion of trenches 134A and 134B that is adjacent to nanosheet channels 112A and 112B. Rather, diffusion regions 140A and 140B have been formed adjacent to nanosheet channels 112A and 112B. Of note, FIGS. 3A and 3B also illustrate that OPLs 132A and 132B have been removed.

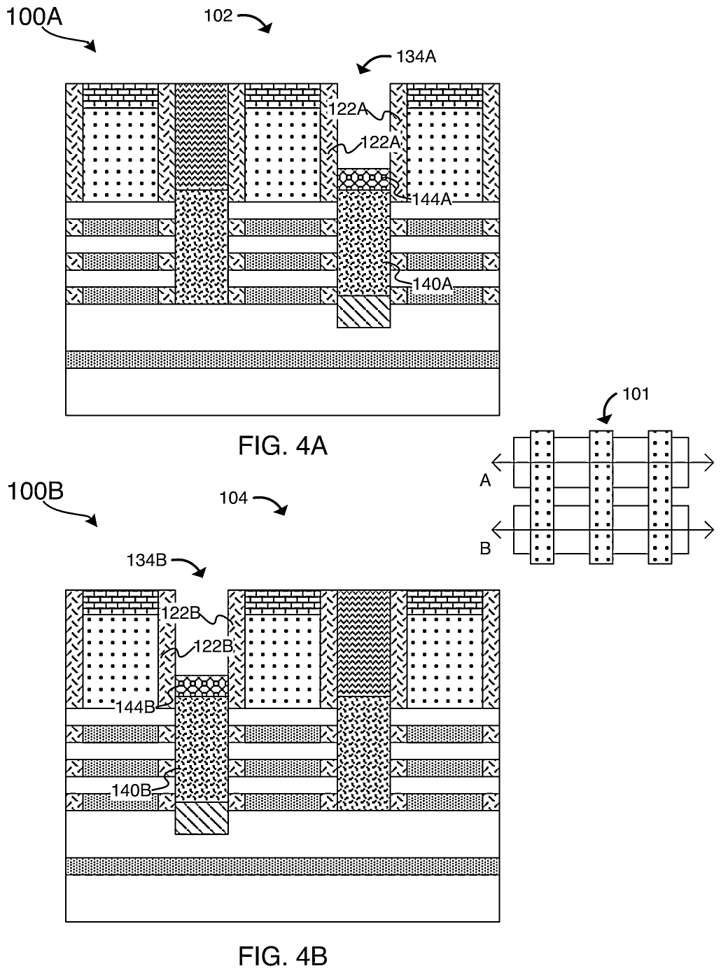

FIGS. 4A and 4B illustrate two cross sectional views 100A and 100B of a fourth intermediate stage of forming the first nanosheet FET 102 and second nanosheet FET 104 with gate extensions, in accordance with embodiments of the present disclosure. In this fourth stage, dielectric masks 144A and 144B have been formed within trenches 134A and 134B upon diffusion regions 140A and 140B. Dielectric masks 144A and 144B have been formed adjacent to gate spacers 122A and 122B. This may have been performed, for example, by filling trenches 134A and 134B with dielectric material and dielectric masks 144A and 144B through an etching process that is selective to spacers 122A and 122B. As such, dielectric masks 144A and 144B may be formed of a different material than gate spacers 122A and 122B. For example, gate spacers 122A and 122B may be formed of silicon nitride (SiN), whereas dielectric masks 144A and 144B may be formed of silicon carbide, silicon carbon-oxide, or aluminum nitride. This would also enable future etching operations to be selective to dielectric masks 144A and 144B but not gate spacers 122A and 122B.

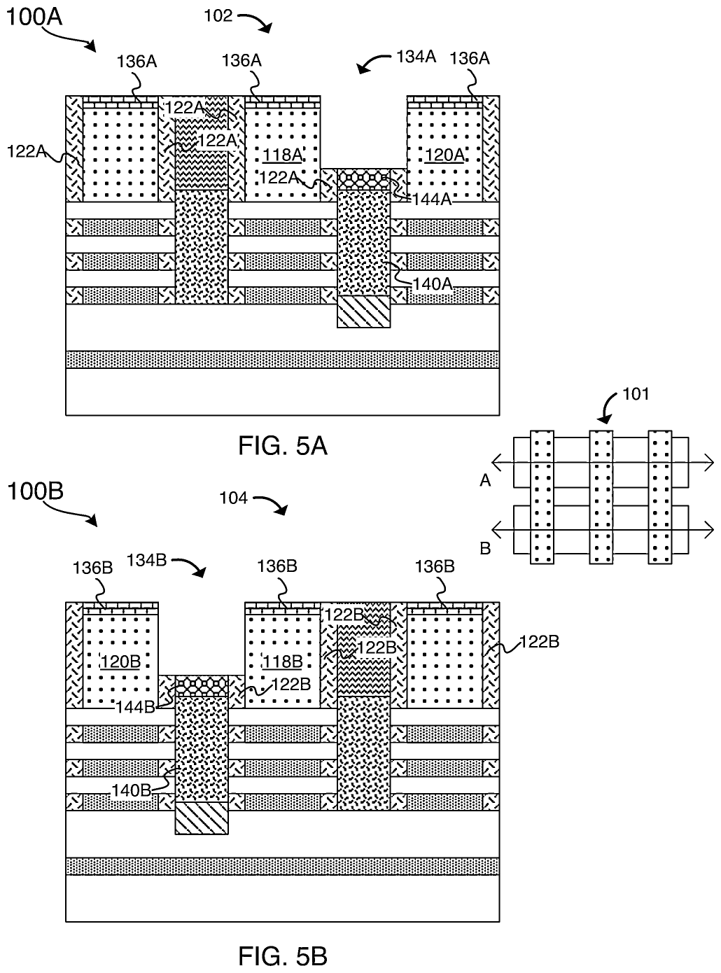

FIGS. 5A and 5B illustrate two cross sectional views of a fifth intermediate stage of forming the first nanosheet FET 102 and second nanosheet FET 104 with gate extensions, in accordance with embodiments of the present disclosure. In this fifth stage, the portions of gate spacers 122A and 122B within trenches 134A and 134B that are not protected by dielectric masks 144A and 144B have been etched away, exposing dummy gate material 118A, 118B, 120A, and 120B within trenches 134A and 134B. This may have been performed, for example, with a non-directional (e.g., isotropic) etch using an etchant that is selective to dielectric masks 144A and 144B. As illustrated in FIGS. 5A and 5B, this etching process has also thinned exposed portions of hardmasks 136A and 136B and gate spacers 122A and 122B that are not within trenches 134A and 134B. In some embodiments, however, these portions could first be covered by a hardmask (e.g., a material similar to dielectric masks 144A and 144B). This may prevent unwanted etching of dummy gate material 118A, 118B, 120A, and 120B in the vertical direction (as illustrated in FIGS. 5A and 5B).

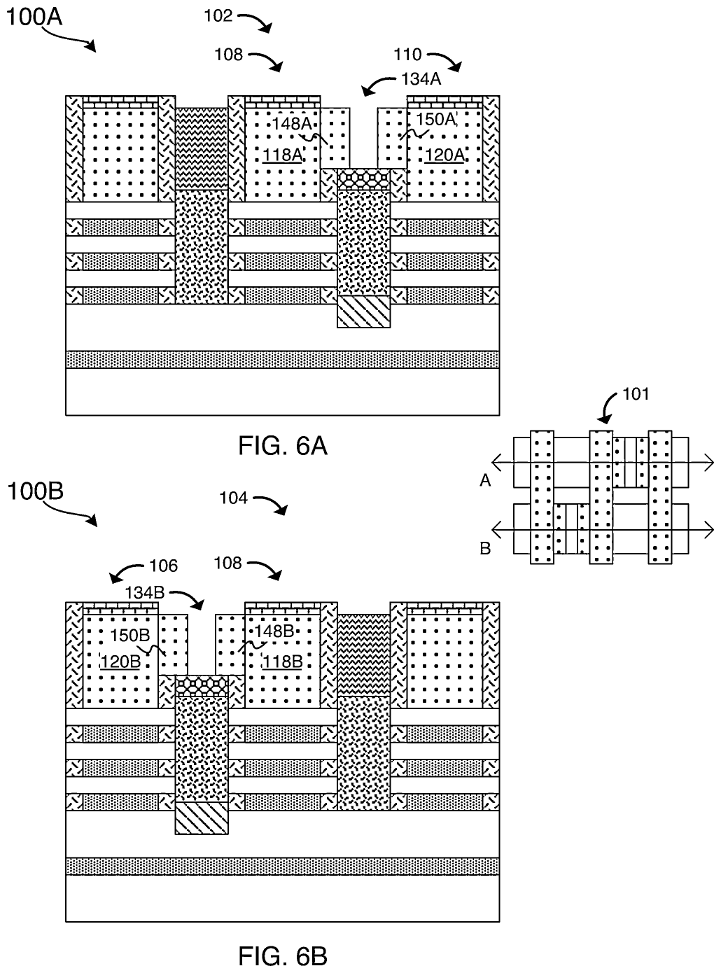

FIGS. 6A and 6B illustrate two cross sectional views 100A and 100B of a sixth intermediate stage of forming the first nanosheet FET 102 and second nanosheet FET 104 with gate extensions, in accordance with embodiments of the present disclosure. In this sixth stage, dummy gate extension material 148A, 148B, 150A, and 150B have been conformally grown within trenches 134A and 134B on dummy gate material 118A, 118B, 120A, and 120B respectively using, for example, a selective epitaxial growth. Of note, trenches 134A and 134B are not completely filled by dummy gate extension material 148A, 148B, 150A, and 150B as illustrated in FIGS. 6A and 6B. As will become clear in future stages of forming first nanosheet FET 102 and second nanosheet FET 104, this may enable the separation of gates in gate regions 108 and 110 in first nanosheet FET 102 and the separation of gates in gate regions 106 and 108 in second nanosheet FET 104.

The separation of dummy gate extension material 148A and 150A and of 148B and 150B may have been accomplished, for example, by timing the conformal growth of dummy gate extension material 148A, 150A, 148B and 150B such that the growth was terminated before trenches 134A and 134B were completely closed. In some embodiments, however, growth may have completely closed trenches 134A and 134B, in which case first and second nanosheet FETs 102 and 104 may have been masked and the opening within trenches 134A and 134B between dummy gate extension material 148A and 150A and 148B and 150B may have been reformed using a directional etch. For the purpose of understanding, the formation of dummy gate extension material 148A, 148B, 150A, and 150B is reflected in legend 101 in FIGS. 6A and 6B.

Dummy gate extension material 148A, 148B, 150A, and 150B may be formed of the same material as dummy gate material 118A, 118B, 120A, and 120B, enabling it to be removed simultaneously when the gates of first and second nanosheet FETs 102 and 104 are formed. As a result, in some instances there may be no distinct barrier between, for example, dummy gate material 118A and 148A. However, dummy gate extension material 148A, 148B, 150A, and 150B is illustrated herein as distinct from dummy gate material 118A, 118B, 120A, and 120B for the purposes of understanding.

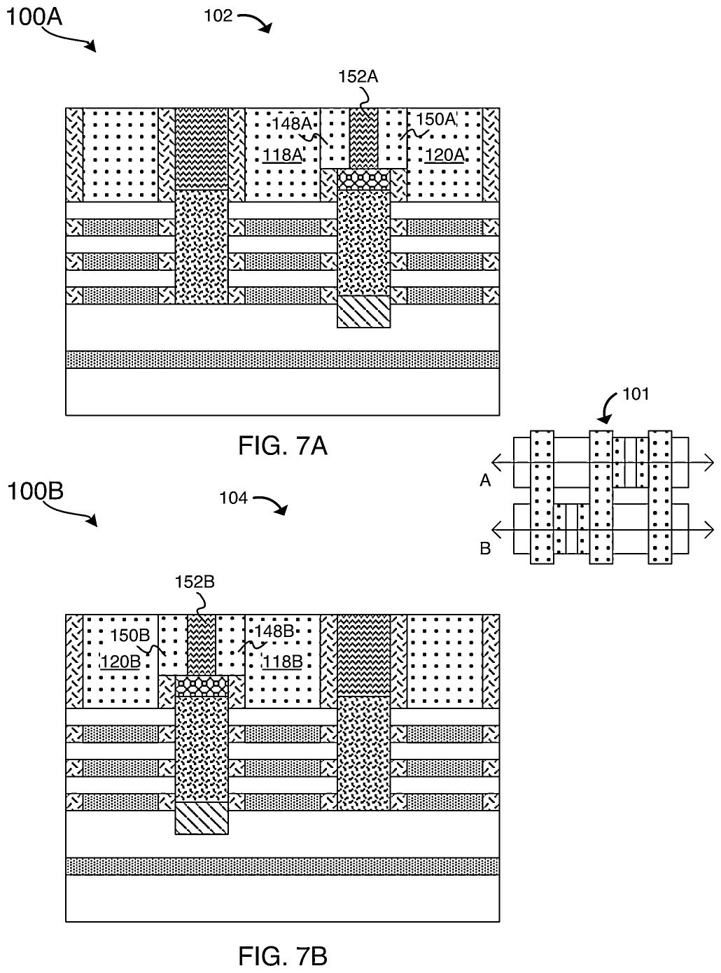

FIGS. 7A and 7B illustrate two cross sectional views 100A and 100B of a seventh intermediate stage of forming the first nanosheet FET 102 and second nanosheet FET 104 with gate extensions, in accordance with embodiments of the present disclosure. In this seventh stage, the remaining portions of trenches 134A and 134B have been filled with dielectric 152A and 152B, separating dummy gate extension material 148A from dummy gate extension material 150A and dummy gate extension material 148B from dummy gate extension material 150B. After forming dielectric 152A and 152B, a planarization process may be performed to remove any excess dielectric material formed on top of first and second nanosheet FETs 102 and 104.

Of note, FIGS. 7A and 7B also illustrate the removal of hardmasks 136A and 136B. This may be performed, for example, using a planarization process such as chemical mechanical planarization. This planarization process may also remove any excess dielectric material from the deposition of dielectric 152A and 152B. Further, if dummy gate extension material 148A and 148B were not applied solely to dummy gate material 118A, 118B, 120A, and 120B using selective epitaxial growth in FIGS. 6A and 6B, this planarization process may also remove excess dummy gate extension material as well.

Of note, while, as illustrated, FIGS. 6A and 6B depict a separate stage from FIGS. 7A and 7B, in some embodiments of the present disclosure these stages may be merged. For example, in some embodiments dielectric 152A and 152B may be formed immediately after the formation of dummy gate extension material 148A, 148B, 150A, and 150B, after which a single planarization process may remove excess dielectric material, excess dummy gate extension material, and hardmasks 136A and 136B.

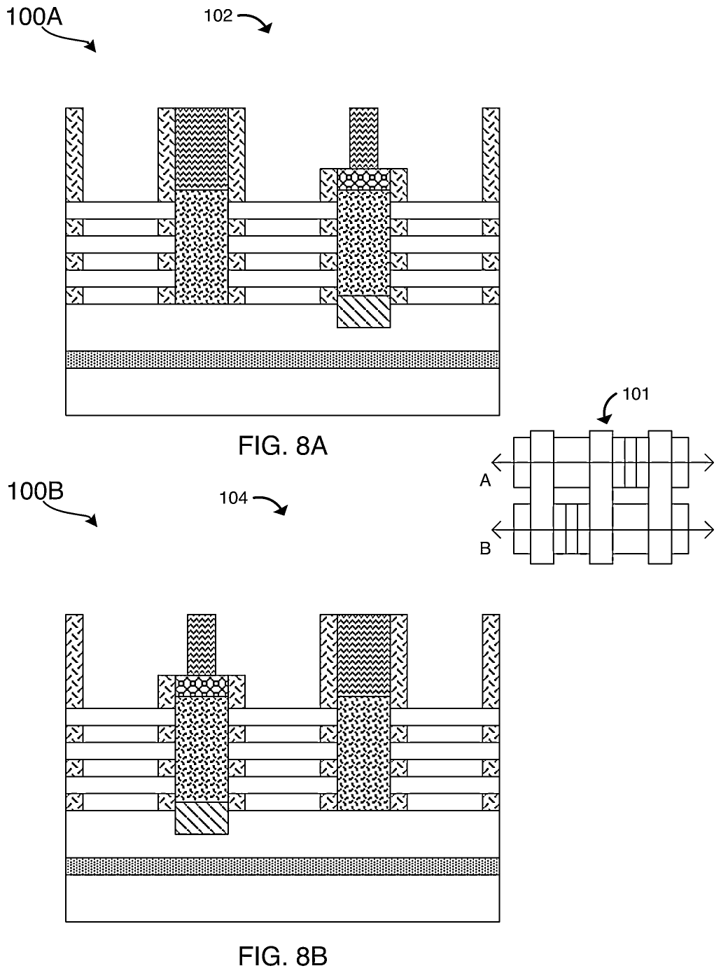

FIGS. 8A and 8B illustrate two cross sectional views 100A and 100B of an eighth intermediate stage of forming the first nanosheet FET 102 and second nanosheet FET 104 with gate extensions, in accordance with embodiments of the present disclosure. In this eighth stage, all dummy gate material, including dummy gate material 118A, 118B, 120A, and 120B, dummy gate extension material 148A, 150A, 148B and 150B, and SiGe regions 130A and 130B that previously surrounded nanosheet channels 112A and 112B have been removed using a wet etch.

For the purpose of understanding, the removal of dummy gate material is reflected in legend 101 in FIGS. 8A and 8B.

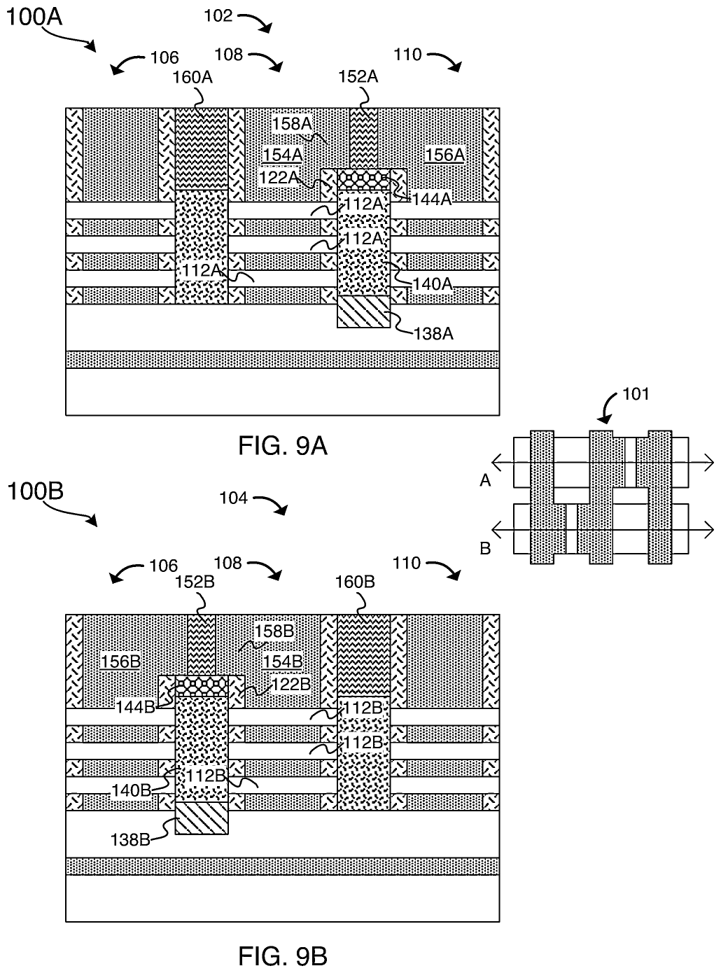

FIGS. 9A and 9B illustrate two cross sectional views 100A and 100B of a ninth intermediate stage of forming the first nanosheet FET 102 and second nanosheet FET 104 with gate extensions, in accordance with embodiments of the present disclosure. In this ninth stage, gate material 154A, 154B, 156A, and 156B has been filled. This has formed gates within first nanosheet FETs 102 and 104. Specifically, gate material 154A surrounds nanosheet channels 112A in nanosheet FET 102 and gate material 154B surrounds nanosheet channels 112B in nanosheet FET 104. Further, gate material 154A (and thus the gate for first nanosheet FET 102), as illustrated, includes gate extension region 158A. Gate extension region 158A, as illustrated, extends over gate spacer 122A, dielectric mask 144A, diffusion region 140A, and placeholder 138A. However, gate extension region 158A, and thus the gate for first nanosheet FET 102, is still separated from gate material 156A by dielectric 152A. The same is true for gate material 154B, which includes gate extension region 158B.

Gate material 154A and 154B, specifically the gate material within gate extension regions 158A and 158B, are separated from diffusion regions 140A and 140B respectively by dielectric masks 144A and 144B. This may prevent current leakage from spreading from gate material 154A and 154B to diffusion regions 140A and 140B. Thus, during operation of nanosheet FETs 102 and 104, dielectric masks 144A and 144B may act as diffusion caps that isolate the gate extension regions from the diffusion regions. As such, dielectric masks 144A and 144B may sometimes be referred to herein as diffusion caps, diffusion-region caps, S/D caps, or S/D region caps.

Of further note, first nanosheet FET 102 is separated from gate region 110 by dielectric 152A and from gate region 106 by dielectric 160A. Similarly, second nanosheet FET 104 is separated from gate region 106 by dielectric 152B and from gate region 110 by dielectric region 160B. However, because of the extensions of the gate for first and second nanosheet FETs 102 and 104, dielectric 152A is smaller in width than dielectric 160A, and dielectric 152B is smaller in width than dielectric 160B. For this reason, dielectrics 152A and 152B may sometimes be referred to herein as reduced dielectric separators, as they are reduced in comparison to standard dielectric separators formed by dielectrics 160A and 160B. Similarly, gate extension regions 158A and 158B may be referred to as adjacent to reduced dielectric separators (i.e., dielectrics 152A and 152B).

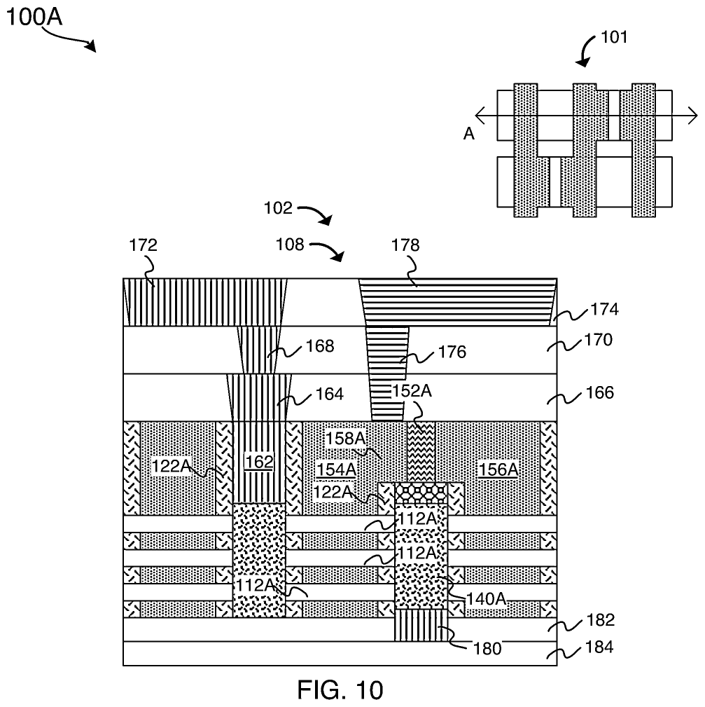

FIG. 10 illustrates a cross sectional view 100A of a tenth stage of forming the first nanosheet FET 102 with a gate extension, in accordance with embodiments of the present disclosure. Of note, view 100B of second nanosheet FET 104 has been omitted from FIG. 10 for the purpose of simplicity, but the features found within the tenth stage of FIG. 10 could also be applied to second nanosheet FET 104.

In this tenth stage, several processing steps that will be understood to a person of skill in the art have been performed to complete the structure of first nanosheet FET 102. For example, dielectric 160A has been removed and replaced with S/D contact 162. Of note, S/D contact 162 is, as illustrated, the same dimensions as dielectric 160A. Thus, dielectric 152A is smaller in width than S/D contact 162. S/D contact 164 has been formed upon S/D contact 162 within interlayer dielectric 166. Of note, while S/D contacts 162 and 164 are illustrated herein as distinct components, in some embodiments there may be no clear distinct separation or transition from S/D contact 162 to S/D contact 164. In other words, S/D contact 162 and S/D contact 164 may be one contiguous component. In these embodiments, dielectric 160A may be referred to as smaller in width than the portion of S/D contact 162 that is below interlayer dielectric 166, that is below the top of gate material 154, or that is below the top of the gate of first nanosheet FET 102.

A further S/D contact via, via 168, has been formed within interlayer dielectric 170. via 168 is connected to back end of the line (BEOL) metal wire 172 (M1) for S/D contact 162, which is formed BEOL ILD layer 174.

FIG. 10 also illustrates gate contact 176, which lands on gate extension region 158A above diffusion region 140A rather than in the center of gate region 108. For that reason, gate contact 176 may be referred to as offset from the center of gate region 108 for first nanosheet FET 102. Gate contact 176 spans through interlayer dielectric 166 and interlayer dielectric 170, and connects to another BEOL wire 178 in the M1 layer for gate contact 176. As illustrated in FIG. 10, because gate contact 176 is offset from the center of gate region 108 and lands on gate extension region 158A, an enlarged space between BEOL metal wire 172 and BEOL wire 178, preventing a short between the two wires. Further, gate contact 176 is also able to be placed further away from S/D contact 164 and via 168, preventing shorts and reducing capacitance between S/D contact 164 and via 168 and gate contact 176.

FIG. 10 also illustrates that silicon substrate 128A has been removed, as has etch-stop layer 126A and silicon epitaxial layer 124A. This may have been performed, for example, by a series of planarization steps that first removed silicon substrate 128A, then removed etch-stop layer 126A and silicon epitaxial layer 125A. At this point, placeholder 138A may have been removed and replaced with backside S/D contact 180. Backside interlayer dielectric 182 is also illustrated as formed around backside S/D contact 180, and backside power delivery network 184 is formed upon backside interlayer dielectric 182, enable connection to backside S/D contact 180.

As discussed with respect to FIGS. 6A and 6B, in some embodiments of the present disclosure, a conformal growth of dummy gate extension material (e.g., dummy gate extension material 148A and 150A) can be terminated before the trench (e.g., trench 134A) in which the material is being formed is completely filled. This may be a cost-effective method of growing dummy gate extension material while still enabling the separation of the eventual gate material between gate regions (e.g., gate material 154A and 156A between gate regions 108 and 110).

However, some embodiments of the present disclosure may take advantage of a larger gate extension that may be possible by allowing the trench in which the dummy gate extension material is being formed to fill completely or almost completely. These embodiments may enable a larger gate extension region to be formed (for example, larger than gate extension region 158A), enabling a larger area for landing a gate contact, in turn enabling a gate contact that is further offset from the center of the gate region, and yet in turn increasing the distance between the gate contact wire and the S/D contact wire in the M1 layer. In these embodiments, a subsequent etching step may be necessary to etch away a portion of the dummy gate extension material that connects the gate regions.

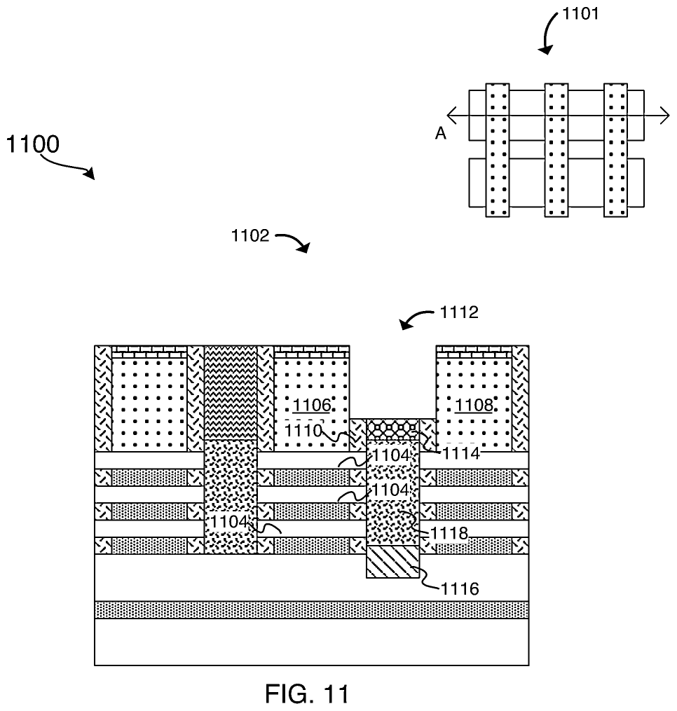

FIGS. 11-15 illustrate an example process of forming such an embodiment of a nanosheet FET 1102. FIGS. 11-15 depict legend 1101. Legend 1101 provides a perspective of where FET 1102 occurs in a larger semiconductor structure. Specifically, line A in legend 1101 represents the cross section presented in cross sectional view 1100 in FIGS. 11-15.

For example, FIG. 11 illustrates a cross sectional view 1100 of a first intermediate stage of forming a nanosheet FET 1102 with a second embodiment of a gate extension, in accordance with embodiments of the present disclosure. FIG. 11 depicts FET 1102 in a similar stage in which FET 102 is illustrated in FIG. 5A. For example, FET 1102 includes nanosheet channels 1104, dummy gate material 1106 and 1108, etched gate spacers 1110, trench 1112, dielectric mask 1114, placeholder 1116, and diffusion region 1118.

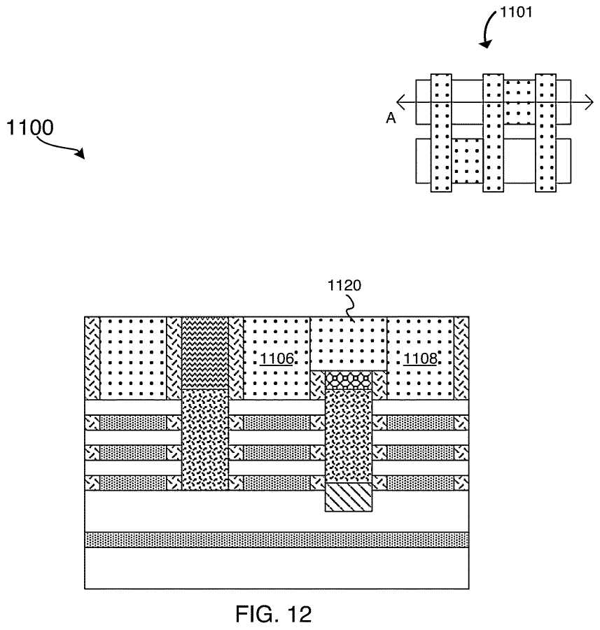

FIG. 12 illustrates a cross sectional view 1100 of a second intermediate stage of forming the nanosheet FET 1102 with the second embodiment of a gate extension, in accordance with embodiments of the present disclosure. In FIG. 12, trench 1112 has been filled with a dummy gate extension material 1120, similar to the stage illustrated in FIG. 6A. However, unlike in FIG. 6A, dummy gate extension material 1120 has completely filled trench 1112. Thus, as illustrated, dummy gate extension material 1120 connects dummy gate material 1106 and 1108. Of note, as illustrated in FIG. 12, the top of FET 1102 may have been planarized after the growth of dummy gate extension material 1120.

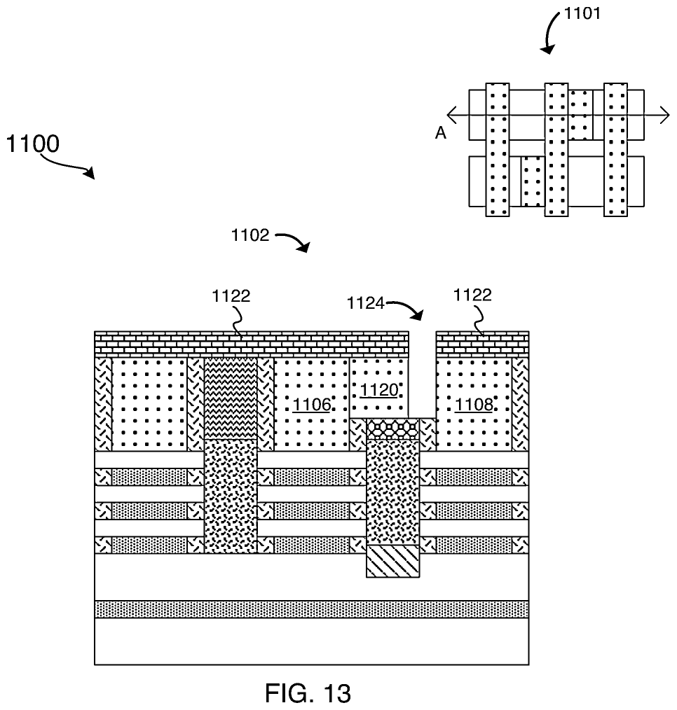

FIG. 13 illustrates a cross sectional view 1100 of a third intermediate stage of forming the nanosheet FET 1102 with the second embodiment of a gate extension, in accordance with embodiments of the present disclosure. In FIG. 13, a mask 1122 (e.g., SiN) has been applied to the top of nanosheet FET 1102 followed by lithography patterning and etching process, enabling the etching of dummy gate extension material 1120 to separate dummy gate extension material 1120 from dummy gate material 1108. This may have been performed with a directional etch, such as reactive ion etching, that is selective to mask 1122. This has resulted in a second trench 1124. As a result of this third stage, dummy gate extension material 1120 may be larger than would be feasible than in embodiments in which dummy gate extension material were formed with no subsequent step to etch the dummy gate extension material. For example, dummy gate extension material 1120 may be larger than dummy gate extension material 148A of FIG. 6A.

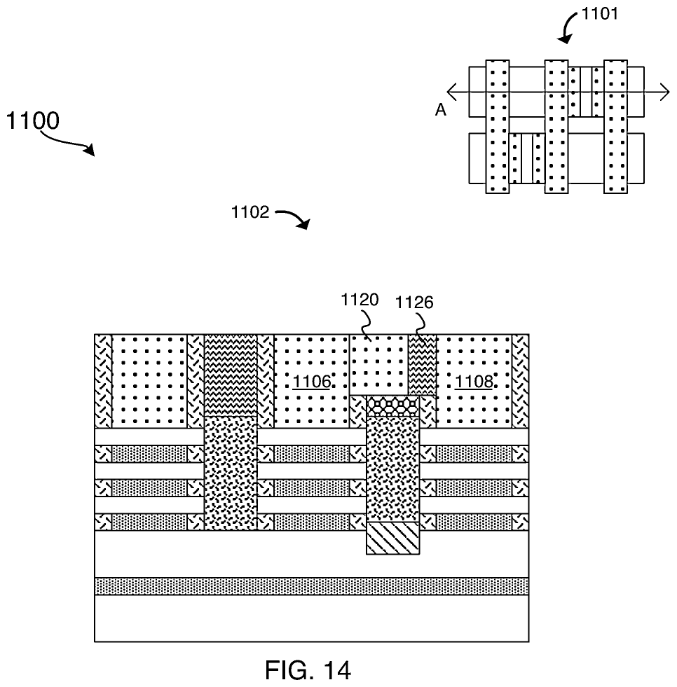

FIG. 14 illustrates a cross sectional view 1100 of a fourth intermediate stage of forming the nanosheet FET 1102 with the second embodiment of a gate extension, in accordance with embodiments of the present disclosure. In FIG. 14, second trench 1124 has been filled with dielectric 1126. In this way, FIG. 14 resembles the seventh intermediate stage of forming nanosheet FET 102, illustrated in FIG. 7A. As a result of the processes performed in FIGS. 12 and 13, dummy gate material 1106 has been connected to dummy gate extension material 1120, but dummy gate material 1108 is connected to little, potentially no dummy gate extension material.

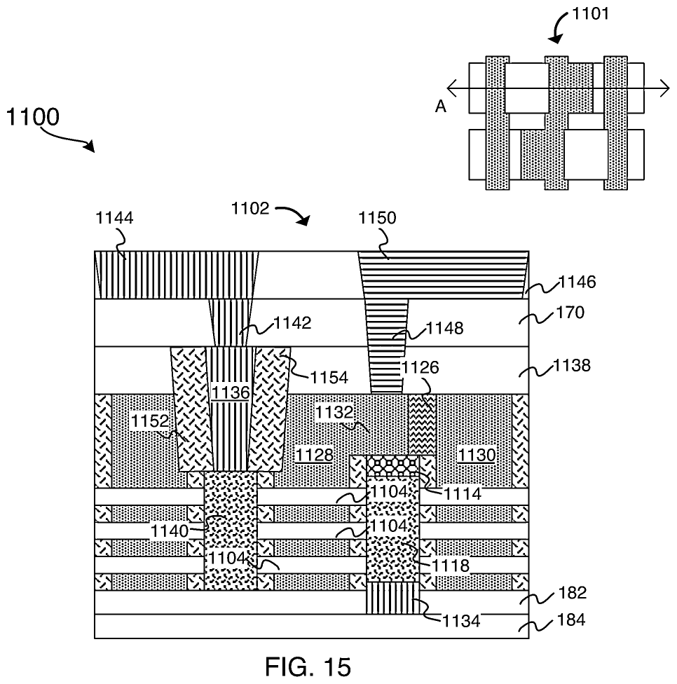

FIG. 15 illustrates a cross sectional view 1100 of a fifth stage of forming the nanosheet FET 1102 with the second embodiment of gate extension, in accordance with embodiments of the present disclosure. This fifth stage resembles the tenth intermediate stage of forming of forming nanosheet FET 102, illustrated in FIG. 10. For example, dummy gate material 1128, 1130, dummy gate extension material 1120, and SiGe regions that previously surrounded nanosheet channels 1104 have been removed using a wet etch. Further, gate material 1128 and 1130 has been filled. This has formed a gate within nanosheet FET 1102. Gate material 1128 (and thus the gate for nanosheet FET 1102), as illustrated, includes gate extension region 1132. Gate extension region 1132, as illustrated, extends over gate spacer 1110, dielectric mask 1114, diffusion region 1118, and backside S/D contact 1134. In some embodiments, gate extension region may extend so far above diffusion region 1118 that no gate extension region could be formed upon gate material 1130 (for example, without risking shorts between the gate extension regions). This embodiment is illustrated in FIG. 15; if no gate extension region could be formed upon gate material 1130 without reducing the width of dielectric 1126 (the already reduced dielectric separator). This is made possible, in these embodiments, by the formation of dummy gate extension material 1120, trench 1124, and dielectric 1126 illustrated in FIGS. 12-14.

FIG. 15 also illustrates S/D contact 1136. Of note, S/D contact 1136 is, as illustrated, a single contiguous component that spans from the top of interdielectric layer 1138 to diffusion region 1140. As illustrated, S/D contact 1136 connects, through via 1142, to wire BEOL metal wire 1144 in M1 layer 1146 for S/D contact 1136.

As illustrated, dielectric 1126 may be referred to as smaller in width than the portion of S/D contact 1136 that is below interlayer dielectric 1138, that is below the top of gate material 1128, or that is below the top of the gate of first nanosheet FET 1102.

FIG. 15 also illustrates gate contact 1148, which spans from the landing point on gate extension region 1132 to BEOL wire 1150 for gate contact 1148 in M1 layer. Because of the large gate extension region 1132, gate contact 1148 is able to be positioned significantly offset from the gate region in which nanosheet channels 1104 are formed. As a further result of this significant offset, a large gap between BEOL metal wire 1144 and BEOL wire 1150 is possible.

Finally, because gate contact 1148 is able to be positioned significantly offset from the gate region in which nanosheet channels 1104 are formed, not all of the original gate material 1128 is necessary for FET 1102 to function. As a result, the gate spacers that would normally surround S/D contact 1136 can be significantly expanded, even at the expense of removing some gate material 1128.

Thus, FIG. 15 illustrates expanded gate spacers 1152 and 1154. Expanded gate spacers 1152 and 1154 may largely replace the traditional gate spacers that would normally surround S/D contact 1136 (for example, the traditional gate spacers 122A that are on either side of S/D contact 162 in FIG. 10). Those traditional gate spacers are oftentimes as narrow as 5 nm. However, because of the ability to expand into the gate material 1128, expanded gate spacers 1152 and 1154 may be as large as 15 nm. This may result in a significantly reduced capacitance between gate material 1128 and S/D contact 1136. Expanded gate spacers 1152 and 1154 may be formed by, after forming gate material 1128 and interlayer dielectric 1138, etching a large contact opening (e.g., the size of expanded gate spacers 1152, 1154, and S/D contact 1136) within interlayer dielectric 1138, gate spacers, gate material 1128, and, forming dielectric spacers 1152/1154 in the contact opening, then filling the remaining opening with S/D contact material (e.g., silicide liner, adhesion metal liner, and conductive metal fill). As a result, expanded gate spacers 1152 and 1154 extend into the gate region of FET 1102 and are above a portion of gate material 1128 (i.e., above a portion of the gate of FET 1102). With expanded gate spacer 1152 and 1154, the parasitic capacitance between the S/D contact 1136 and gate material 1128 is reduced.

As illustrated in FIG. 15, the etching of the contact opening into gate material 1128 results in a tapered shape of gate material 1128 (i.e., the gate of FET 1102) opposite of the gate expansion region 1132. In some embodiments, this tapered shape by itself may reduce the risk of parasitic capacitance the S/D contact 1136 and gate material 1128, even without expanded gate spacers, because the amount of gate material near S/D contact 1136 is reduced. However, as illustrated, expanded gate spacer 1145 interfaces with this tapered portion of the gate, further reducing parasitic capacitance.

Some embodiments of the present disclosure can be illustrated as a semiconductor device comprising a nanosheet field effect transistor (FET). The nanosheet FET comprises a diffusion region that connects to a backside power delivery network. The nanosheet FET also comprises a gate in a first gate region. The gate comprises a first gate extension region that extends over the diffusion region. The gate extension region enables greater flexibility in positioning a gate contact, which can avoid potential device shorts and capacitance issues.

In some embodiments of the semiconductor device, the nanosheet FET is separated from a second gate region by a reduced dielectric separator. The reduced dielectric separator may prevent the gate of the nanosheet FET from shorting to gate material of the second gate region while still enabling the gate of the nanosheet FET to extend into the gate extension region.

In some embodiments of the semiconductor device in which the nanosheet FET is separated from a second gate region by a reduced dielectric separator, the second gate region comprises gate material that is not connected to a gate extension region. This may further enable the gate of the nanosheet FET to extend over the diffusion region, adding greater flexibility in positioning the gate contact.

In some embodiments of the semiconductor device, the semiconductor device comprises a second gate region and the second gate region comprises a second gate extension region. This second gate extension region may also extend over the diffusion region. These embodiments may be particularly efficient to manufacture.

In some embodiments of the semiconductor device, the nanosheet FET further comprises a source/drain (S/D) contact that is surrounded by expanded gate spacers. These expanded gate spacers may reduce the risk of shorts between the S/D contact and the gate.

In some embodiments of the semiconductor device with the expanded gate spacers, the expanded gate spacers extend into the first gate region above a portion of the gate. This may enable even thicker expanded gate spacers, further reducing the risk of shorts.

In some embodiments of the semiconductor device, the gate has a tapered shape opposite the first gate extension region. This may reduce the risk of capacitance issues in the device.

In some embodiments of the semiconductor device in which the gate has a tapered shape, nanosheet FET further comprises expanded gate spacers that interface with the tapered portion of the gate.

In some embodiments of the semiconductor device, a diffusion-region cap separates the diffusion region and the first gate extension. This cap may prevent shorts between the gate extension region and the diffusion region.

Some embodiments of the present disclosure can also be illustrated by a nanosheet FET. The nanosheet FET comprises a diffusion region that connects to a backside power delivery network. The nanosheet FET also comprise a gate in a first gate region. The gate comprises a first gate extension region that extends over the diffusion region. The gate extension region enables greater flexibility in positioning a gate contact, which can avoid potential device shorts and capacitance issues.

In some embodiments of the nanosheet FET, the nanosheet FET is separated from a second gate region by a reduced dielectric separator. The reduced dielectric separator may prevent the gate of the nanosheet FET from shorting to gate material of the second gate region while still enabling the gate of the nanosheet FET to extend into the gate extension region.

In some embodiments of the nanosheet FET in which the nanosheet FET is separated from the second gate region, the extension of the gate extension region over the diffusion region prevents the formation of a second gate extension in the second gate region. This further extension of the gate extension region adds greater flexibility in positioning the gate contact.

In some embodiments of the nanosheet FET, the diffusion the diffusion region is beneath a second gate extension region of a second gate region. These embodiments may be particularly efficient to manufacture.

In some embodiments of the nanosheet FET, the nanosheet FET further comprises a source/drain contact that is surrounded by expanded gate spacers. These expanded gate spacers may reduce the risk of shorts between the S/D contact and the gate.

In some embodiments of the nanosheet FET, the expanded gate spacers extend into the first gate region above a portion of the gate. This may enable even thicker expanded gate spacers, further reducing the risk of shorts.

In some embodiments of the nanosheet FET, the gate has a tapered shape opposite the first gate extension. This may reduce the risk of capacitance issues in the device.

In some embodiments of the nanosheet FET in which the gate has a tapered shape, nanosheet FET further comprises expanded gate spacers that interface with the tapered portion of the gate.

In some embodiments of the nanosheet FET, the nanosheet FET further comprises a diffusion-region cap that separates the diffusion region and the first gate extension region. This cap may prevent shorts between the gate extension region and the diffusion region.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a nanosheet field effect transistor (FET) comprising:
a diffusion region that connects to a backside power delivery network;
a gate in a first gate region, wherein the gate comprises a first gate extension region that extends over the diffusion region.

2. The semiconductor device of claim 1, wherein the nanosheet FET is separated from a second gate region by a reduced dielectric separator.

3. The semiconductor device of claim 2, wherein the second gate region comprises gate material that is not connected to a gate extension region.

4. The semiconductor device of claim 1, further comprising a second gate region, wherein the second gate region comprises a second gate extension region that extends over the diffusion region.

5. The semiconductor device of claim 1, wherein the nanosheet FET further comprises a source/drain (S/D) contact, wherein the S/D contact is surrounded by expanded gate spacers.

6. The semiconductor device of claim 5, wherein the expanded gate spacers extend into the first gate region above a portion of the gate.

7. The semiconductor device of claim 1, wherein the gate has a tapered shape opposite the first gate extension region.

8. The semiconductor device of claim 1, wherein a diffusion-region cap separates the diffusion region and the first gate extension.

9. A nanosheet field effect transistor (FET) comprising:
a diffusion region that connects to a backside power delivery network;
a gate in a first gate region, wherein the gate comprises a first gate extension region that extends over the diffusion region.

10. The nanosheet FET of claim 9, wherein the nanosheet FET is separated from a second gate region by a reduced dielectric separator.

11. The nanosheet FET of claim 10, wherein the extension of the gate extension region over the diffusion region prevents the formation of a second gate extension in the second gate region.

12. The nanosheet FET of claim 9, wherein the diffusion region is beneath a second gate extension region of a second gate region.

13. The nanosheet FET of claim 9, further comprising a source/drain contact that is surrounded by expanded gate spacers.

14. The nanosheet FET of claim 13, wherein the expanded gate spacers extend into the first gate region above a portion of the gate.

15. The nanosheet FET of claim 9, wherein the gate has a tapered shape opposite the first gate extension.

16. The nanosheet FET of claim 9, further comprising a diffusion-region cap that separates the diffusion region and the first gate extension region.
